(19) United States
(12) Patent Application Publication
(10) Pub. No.: US 2026/0228383 A1
(43) Pub. Date: Aug. 6, 2026

(54) Method for implementing EDA data parametric modeling

(71) Applicant: XPEEDIC CO., LTD., Shanghai (CN)

(72) Inventors: Wenliang DAI, Shanghai (CN); Liu YU, Shanghai (CN); Liguo JIANG, Shanghai (CN); Yunzhu DU, Shanghai (CN); Bin LUO, Shanghai (CN)

(73) Assignee: XPEEDIC CO., LTD., Shanghai (CN)

(21) Appl. No.: 19/144,469

(22) PCT Filed: Dec. 15, 2023
(86) PCT No.: PCT/CN2023/139021

§ 371 Date: Jun. 28, 2025

(30) Foreign Application Priority Data
Oct. 10, 2023 (CN) 202311310916.2

(51) Int. Cl. G06F 30/20

(52) U.S. Cl. CPC G06F 30/20

(57) ABSTRACT

The present invention provides a method for implementing EDA data parametric modeling, comprising: constructing three mapping tables when performing attribute parameterization operations on a single or batch commands; performing parameterization on a single or batch commands; and affecting all entities parameterized by parameters when modifying parameter values. The method realizes batch modification of model data, group control of parameters, supporting Redo/Undo.

### TECHNICAL FIELD

The present invention relates to the technical field of EDA model layout simulation, and in particular relates to a method for implementing EDA data parametric modeling.

### BACKGROUND TECHNOLOGY

A function of EDA model data parametric modeling is to use one or more attributes of the command in the model, such as offset, height, etc. as parameters, and size, position, etc. of the entity as driven factors. By processing and calculating the parameters and related attributes through internal logic of a program, the driven elements are driven to change, thereby generating a model that meets the requirements. A process of establishing association between parameters and driven elements is called parameterization.

EDA model data parameterization, grouping model data to achieve the effect that by modifying a parameter once, a whole set of data is modified together. Users do not need to make positioning modifications one by one on the 3D interface, which is especially obvious for efficiency improvement when the model data volume is large, making model update and modification more flexible and convenient, and accelerating product launch.

### SUMMARY OF THE INVENTION

In view of the above problems, the present invention is proposed to provide a method for implementing EDA data parametric modeling that overcomes the above problems or at least partially solves the above problems.

According to one aspect of the present invention, a method for implementing EDA data parameterized modeling is provided, the method comprising:
constructing three mapping tables when performing attribute parameterization operations on a single or batch commands;
performing parameterization on a single or batch commands; and
affecting all entities parameterized by parameters when modifying parameter values.

Optionally, the step of constructing three mapping tables when performing attribute parameterization operations on a single or batch commands comprises:
a global mapping table of entities and related commands, wherein there is a unique entity ID for different entities of an EDA model and a unique command ID for each command of an entity;
establishing a global parameterization mapping table; and
for a single command that supports parameterization, constructing a mapping table between attribute types and parameter names.

Optionally, the unique ID is important for data search, not only to help with data search, but also to reduce an amount of data in the mapping table; the mapping table comprises all entity-command correspondences.

Optionally, the step of establishing a global parameterization mapping table comprises:
entity IDs, command IDs are unique, and there is also a unique attribute type identifier for each attribute of a command to form a tuple with the three data types;
constructing a mapping table GMAP2 using a linked list consisting of parameter names and tuples, wherein the mapping table comprises all parameterized data.

Optionally, for a single command that supports parameterization, constructing a mapping table between attribute types and parameter names comprises:
when the mapping table comprises a certain attribute type, it indicates that the attribute has been parameterized, and a parameter name corresponding to the attribute type is a parameterized name;
when the mapping table does not comprise an attribute being operated on, it indicates that the attribute has not been parameterized.

Optionally, the step of performing parameterization on a single or batch commands comprises:
constructing GMAP2, with a parameterized name input by users as a key value of the mapping table, and the linked list consisting of the tuples of the entity IDs, command IDs, and attribute types associated with the parameter name as a value of the mapping table; adding the mapping table MAP3 consisting of the attribute types and parameter names of a single or multiple commands being operated, and updating specific parameterized values to the attributes corresponding to the commands;
if original data is a value instead of a parameter name, deleting mapping data of the attribute types and parameter names in MAP3 added in a previous step, and updating command attributes;
if the original data is a parameter name, deleting the mapping data of the attribute types and parameter names in MAP3 added in the previous step, and adding the mapping data consisting of the attribute types and the original data in MAP3; and
recalculating and rendering associated entities.

Optionally, the step of affecting all entities parameterized by parameters when modifying parameter values comprises:
by traversing GMAP2, finding all associated entity IDs, command IDs, and tuple lists of attributes that need to be updated in the command;
finding a corresponding command in GMAP1 using found entity IDs and command IDs, and then setting new values to corresponding attributes of the command found in the previous step and its MAP3;
when performing Undo operation, it is also necessary to traverse GMAP2 to find the tuple linked list of all associated entity IDs, command IDs, and attribute types, and then finding the corresponding command that needs to be Undo in GMAP1 through the found entity ID and command ID, and setting data to be restored to the corresponding attributes of the command to be Undo and MAP3.

The present invention provides a method for implementing EDA data parametric modeling, comprising: constructing three mapping tables when performing attribute parameterization operations on a single or batch commands; performing parameterization on a single or batch commands; and affecting all entities parameterized by parameters when modifying parameter values. The method realizes functions of batch modification of model data and group control of parameters, and supports Redo/Undo.

The above description is only an overview of the technical solution of the present invention. In order to more clearly understand the technical means of the present invention, it can be implemented according to the contents of the specification. In order to make the above and other purposes, features and advantages of the present invention more obvious and easy to understand, the specific implementation methods of the present invention are listed below.

### BRIEF DESCRIPTION OF THE DRAWINGS

In order to more clearly illustrate the technical solutions of the embodiments of the present invention, the drawings required for use in the description of the embodiments will be briefly introduced below. Obviously, the drawings described below are only some embodiments of the present invention. For ordinary technicians in this field, other drawings can be obtained based on these drawings without creative work.

FIG. 1 is a data processing flow chart of a parameterization operation according to an embodiment of the present invention;

FIG. 2 is a schematic diagram of a GMAP1 and MAP3 mapping relationship constructed by the parameterization operation according to an embodiment of the present invention;

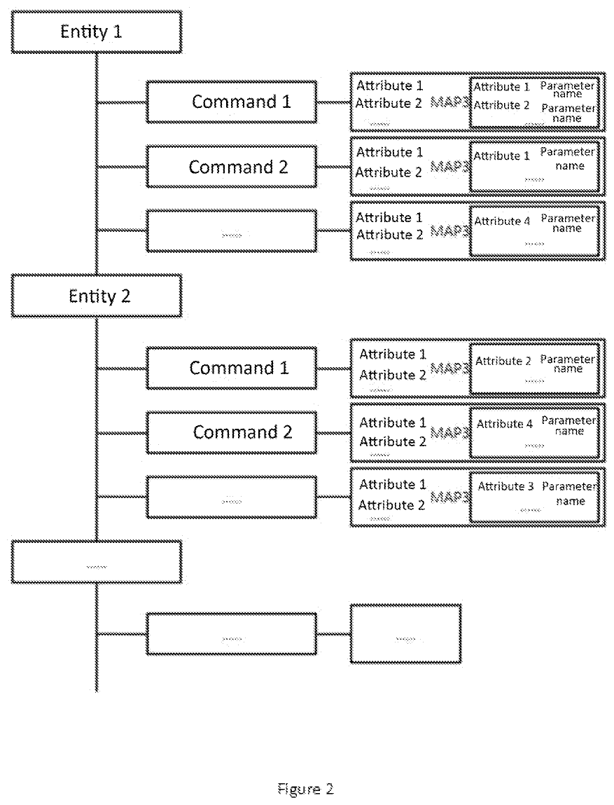

FIG. 3 is a schematic diagram of a GMAP2 mapping relationship constructed by the parameterization operation according to an embodiment of the present invention.

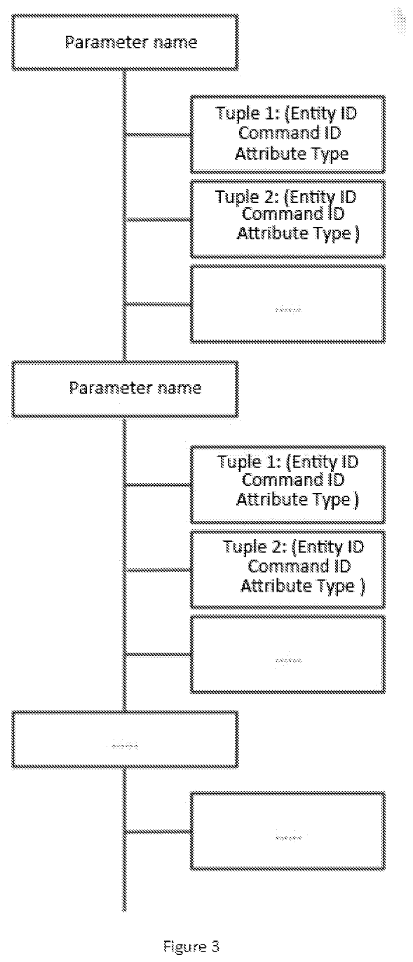

### SPECIFIC EMBODIMENTS

The exemplary embodiments of the present disclosure will be described in more detail below with reference to the accompanying drawings. Although the exemplary embodiments of the present disclosure are shown in the accompanying drawings, it should be understood that the present disclosure can be implemented in various forms and should not be limited by the embodiments set forth herein. On the contrary, these embodiments are provided to enable a more thorough understanding of the present disclosure and to fully convey the scope of the present disclosure to those skilled in the art.

The terms “comprise/comprises/comprising” and “have/has/having” in the description embodiments, claims and drawings of the present invention and any variations of these terms are intended to cover non-exclusive inclusions, for example, including a series of steps or units.

The technical solution of the present invention is described in further detail below in connection with the accompanying drawings and embodiments.

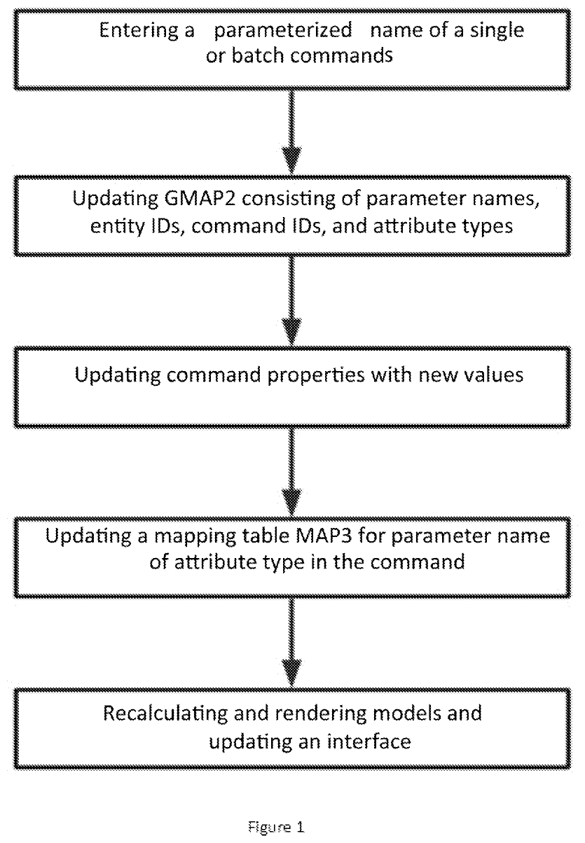

As shown in FIG. 1, a method for implementing EDA data parametric modeling comprises:
1. Constructing three mapping tables when performing attribute parameterization operations on a single or batch commands
1.1 A global mapping table of entities and related commands (referred to as GMAP 1), wherein there is a unique entity ID for different entities of an EDA model and a unique command ID for each command of an entity. The unique ID is important for data search, not only to help with data search, but also to reduce an amount of data in the mapping table; the mapping table comprises all entity-command correspondences.
1.2 A global parameterization mapping table (referred to as GMAP2). Entity IDs, command IDs are unique, and there is also a unique attribute type identifier for each attribute of a command to form a tuple with the three data types.
1.3 For a single command that supports parameterization, constructing a mapping table between attribute types and parameter names (referred to as MAP3). When the mapping table comprises a certain attribute type, it indicates that the attribute has been parameterized, and a parameter name corresponding to the attribute type is a parameterized name; when the mapping table does not comprise an attribute being operated on, it indicates that the attribute has not been parameterized.

A parameterization process of a single or batch command is as follows: The GMAP1 mapping table has been built when a command is created, so only GMAP2 and MAP3 need to be built during parameterization, with parameterization steps as follows: constructing GMAP2, with a parameterized name input by users as a key value of the mapping table, and the linked list consisting of the tuples of the entity IDs, command IDs, and attribute types associated with the parameter name as a value of the mapping table; adding the mapping table MAP3 consisting of the attribute type and parameter name of a single or multiple commands being operated, and updating specific parameterized values to the attributes corresponding to the commands; finally, recalculating and rendering associated entities. When performing an Undo operation, command attributes need to be restored with original data, and the corresponding tuples of the entity IDs, command IDs, and attribute types are removed from GMAP2. There are two cases for processing commands:
2.1 If original data is a value instead of a parameter name, deleting mapping data of the attribute type and parameter name in MAP3 added in a previous step, and updating command attributes;
2.2 If the original data is a parameter name, deleting the mapping data of the attribute types and parameter names in MAP3 added in the previous step, and adding the mapping data consisting of the attribute types and the original data in MAP3.

Finally, recalculating and rendering associated entities.

When a value of a parameter is modified, it will affect all entities parameterized by the parameter, with a method as follows: by traversing GMAP2, finding all associated entity IDs, command IDs, and tuple lists of attributes that need to be updated in the command; then finding the corresponding command in GMAP1 using the found entity ID and command ID, and then setting a new value to the corresponding attribute of the command found in the previous step and its MAP3. When performing the Undo operation, it is also necessary to traverse GMAP2 to find the tuple linked list of all associated entity IDs, command IDs, and attribute types, and then find the corresponding command that needs to be Undo in GMAP1 through found entity IDs and command IDs, and set data to be restored to corresponding attributes of the command to be Undo and its MAP3.

The present invention provides a method for batch modifying multiple model data at one time by using parameter names input by users to represent model data. By establishing a mapping relationship table between user-defined parameter names and entities, commands, and attributes, a method for synchronously updating multiple model data by modifying data once is implemented, supporting Redo/Undo, and promoting batch and efficient modification of data to establish satisfying models. Beneficial effects: The present invention realizes functions of batch modification of model data, group control of parameters, and supports Redo/Undo, making the way for users to operate model data more efficient and convenient. When performing equal value modification on a group of model data in the prior art, it is necessary to search one by one, select them one by one, and then modify parameters. With the present invention, only a parameter name needs to be associated to perform batch modification operations on the model data, which greatly facilitates the user to perform data operations.

The above specific embodiments further illustrate the purpose, technical solutions and beneficial effects of the present invention in detail. It should be understood that the above are only specific implementation methods of the present invention and are not intended to limit the scope of protection of the present invention. Any modifications, equivalent substitutions, improvements, etc. made within the spirit and principles of the present invention should fall within the scope of protection of the present invention.

What is claimed is:

1. A method for implementing EDA data parametric modeling, comprising:
constructing three mapping tables when performing attribute parameterization operations on a single or batch commands;
performing parameterization on a single or batch commands; and
affecting all entities parameterized by parameters when modifying parameter values.

2. The method for implementing EDA data parametric modeling according to claim 1, wherein the step of constructing three mapping tables when performing attribute parameterization operations on a single or batch commands comprises:
a global mapping table of entities and related commands, wherein there is a unique entity ID for different entities of an EDA model and a unique command ID for each command of an entity;
establishing a global parameterization mapping table; and
for a single command that supports parameterization, constructing a mapping table between attribute types and parameter names.

3. The method for implementing EDA data parametric modeling according to claim 2, wherein the unique ID is important for data search, not only to help with data search, but also to reduce an amount of data in the mapping table; the mapping table comprises all entity-command correspondences.

4. The method for implementing EDA data parametric modeling according to claim 2, wherein the step of establishing a global parameterization mapping table comprises:
entity IDs, command IDs are unique, and there is also a unique attribute type identifier for each attribute of a command to form a tuple with the three data types;
constructing a mapping table GMAP2 using a linked list consisting of parameter names and tuples, wherein the mapping table comprises all parameterized data.

5. The method for implementing EDA data parametric modeling according to claim 2, wherein for a single command that supports parameterization, constructing a mapping table between attribute types and parameter names comprises:
when the mapping table comprises a certain attribute type, it indicates that the attribute has been parameterized, and a parameter name corresponding to the attribute type is a parameterized name;
when the mapping table does not comprise an attribute being operated on, it indicates that the attribute has not been parameterized.

6. The method for implementing EDA data parametric modeling according to claim 1, wherein the step of performing parameterization on a single or batch commands comprises:
constructing GMAP2, with a parameterized name input by users as a key value of the mapping table, and the linked list consisting of tuples of the entity IDs, command IDs, and attribute types associated with the parameter name as a value of the mapping table; adding the mapping table MAP3 consisting of the attribute types and parameter name of a single or multiple commands being operated, and updating specific parameterized values to the attributes corresponding to the commands;
if original data is a value instead of a parameter name, deleting mapping data of the attribute types and parameter names in MAP3 added in a previous step, and updating command attributes;
if the original data is a parameter name, deleting the mapping data of the attribute types and parameter name in MAP3 added in the previous step, and adding the mapping data consisting of the attribute types and the original data in MAP3; and
recalculating and rendering associated entities.

7. The method for implementing EDA data parametric modeling according to claim 1, wherein the step of affecting all entities parameterized by parameters when modifying parameter values comprises:
by traversing GMAP2, finding all associated entity IDs, command IDs, and tuple lists of attributes that need to be updated in the command;
finding a corresponding command in GMAP1 using found entity IDs and command IDs, and then setting new values to corresponding attributes of the command found in the previous step and its MAP3;
when performing Undo operation, it is also necessary to traverse GMAP2 to find the tuple linked list of all associated entity IDs, command IDs, and attribute types, and then finding the corresponding command that needs to be Undo in GMAP1 through the found entity ID and command ID, and setting data to be restored to the corresponding attributes of the command to be Undo and MAP3.
